(19) United States
(12) Patent Application Publication
(10) Pub. No.: US 2025/0326009 A1
(43) Pub. Date: Oct. 23, 2025

(54) COMPOSITE CLEANING PROCESS AND SYSTEM

(71) Applicant: HIGHLIGHT TECH CORP., Tainan City (TW)

(72) Inventors: CHWUNG-SHAN KOU, Tainan City (TW); WEN-YUNG YEH, Tainan City (TW); CHANG-YING CHEN, Tainan City (TW)

(73) Assignee: HIGHLIGHT TECH CORP., Tainan City (TW)

(21) Appl. No.: 18/747,573

(22) Filed: Jun. 19, 2024

(30) Foreign Application Priority Data
Apr. 19, 2024 (TW) 113114787

(51) Int. Cl. B08B 7/04; B08B 3/04; B08B 3/08; B08B 3/10; B08B 5/00; B08B 7/00; H01L 21/02

(52) U.S. Cl. CPC B08B 7/04; B08B 3/041; B08B 3/08; B08B 3/10; B08B 5/00; B08B 7/0007; B08B 7/0042; B08B 2203/005; H01L 21/02057

(57) ABSTRACT

Disclosed are a composite cleaning process and a composite cleaning system used for performing the composite cleaning process. The composite cleaning system comprises a carrier, a laser cleaning device, and a gas or liquid cleaning device. The carrier is used to carry at least one object, and the object has at least one to-be-cleaned target located on a to-be-cleaned area of the object. A composite cleaning step of the composite cleaning process comprises using the laser cleaning device to perform a laser reactive cleaning step on the to-be-cleaned area of the object and using the gas or liquid cleaning device to perform a gas or liquid reactive cleaning step on the to-be-cleaned area of the object. Thereby, either the laser reactive cleaning step or the gas or liquid reactive cleaning step is assisted by the other to improve a cleaning effect of the to-be-cleaned target.

### CROSS-REFERENCE TO RELATED APPLICATION

This application claims priority from Taiwan Patent Application No. 113114787, filed on Apr. 19, 2024, each of which is hereby incorporated herein by reference in its entireties.

### BACKGROUND OF THE DISCLOSURE

### 1. Field of Disclosure

The disclosure relates to cleaning process and system, more particularly to a composite cleaning process and system.

### 2. Related Art

There are five major pollutants in the semiconductor wafer manufacturing process: particles, metal impurities (such as metal ions), organic pollutants, native oxide layer, and micro-rough structure on the wafer surface. The manufacturing process of semiconductor wafers is quite complex, and every step included in the front-end-of-line or the back-end-of-line, such as etching, oxidation, deposition, photoresist removal, chemical-mechanical polishing, packaging, and dicing, etc., is a source of wafer surface contamination. These contaminations have a considerable impact on process quality and yield, so the wafer manufacturing process must undergo repeated cleaning processes. Moreover, with the development of extra large integrated circuits (VLSI, ULSI), the requirements for wafer cleanliness have become more stringent. Currently, industries often use the RCA standard clean method to clean wafers. The RCA standard clean method was developed by RCA in the 1960s and has been used for quite a long time. The reason is that there is currently no new cleaning technique that can effectively replace it (SC-1, also known as APM; SC-2, also known as HPM). Taking cleaning substrates as an example, the conventional techniques use SPM/SC-1 cleaning formula, SC-2/SPM/DHF cleaning formula and SC-1 cleaning formula as reactive cleaning ingredients to perform one cleaning step or more than one cleaning step. Taking cleaning of objects that have completed the front-end-of-line (FEOL) as an example, conventional techniques use SPM/SC-1 cleaning formula, SC-2/SPM/DHF cleaning formula and SPM cleaning formula as reactive cleaning ingredients to perform one cleaning step or more than one cleaning step. Taking cleaning of objects that have completed the back-end-of-line (BEOL) as an example, conventional techniques use EKC, NMP, IPA, ACE solvents or solutions as cleaning formulas to perform one cleaning step or more than one cleaning step, wherein NMP is N-methylpyrrolidone, the EKC solution is a mixed solution containing NMP (N-methylpyrrolidone) solvent and an alkaline amine, IPA is isopropyl alcohol, and ACE is acetone. Taking the cleaning of packaged objects as an example, conventional techniques use EKC, NMP, IPA, ACE solvents or solutions as cleaning formulas to perform one cleaning step or more than one cleaning step. However, traditional cleaning processes consume large amounts of water and generate large amounts of hazardous waste emissions.

Furthermore, process nanonization and “green production” are common trends in the development of high-tech industries currently and in the future, including deep sub-micron semiconductors, TFT-LCD, III-V communication components, ultra-precision processing, nanomaterial manufacturing and nano-electronic components are actively researching and developing in the direction of ultra-fine and ultra-clean. In the nano-processing environment, even if there are very small amounts of contaminants in any link, such as micro-particles, metal impurities, organic matters or polymers, etc., may cause great harm to the process yield. However, such increasingly stringent process cleanliness requirements can no longer be met through the RCA cleaning technique of traditional electronic processes. Moreover, these processes with high water consumption and high pollutant water emissions will seriously affect the development of high-tech electronics industry.

Although there is currently a technique that uses ozone for cleaning, due to the low solubility of ozone in aqueous solutions and its sensitivity to environmental variables, it is easily affected by the concentration of gas phase ozone, solution temperature and pH, resulting in unstable cleaning efficiency. In addition, although the current technique simply attempts to change the physical conditions, such as improving the temperature and pressure operating range of the ozone-deionized water vapor-liquid contact system and cleaning system to increase the ozone-deionized water concentration and increase the reaction rate, the improvements are limited, resulting in the ozone-deionized water technique still not being widely used in manufacturing processes.

In controlling of physical conditions, although improving control of the temperature and pressure operating range of the ozone-deionized water vapor-liquid contact system and cleaning system is performed in order to increase the ozone-deionized water concentration and increase the reaction rate, the efficiency in practical applications is still not ideal. The reason is that simply changing the physical conditions to approach the thermodynamic ozone saturated concentration will have limited improvement in improving ozone-deionized water concentration, resulting in the ozone-deionized water technique still not being widely used in manufacturing processes.

### SUMMARY OF THE DISCLOSURE

In view of the above-mentioned problems of the conventional techniques, an object of the disclosure is to provide a composite cleaning process and a composite cleaning system capable of meeting the increasingly stringent process cleanliness requirements.

In order to achieve the aforementioned object, the disclosure discloses a composite cleaning process at least comprising following steps of: providing at least one object, the object having at least one to-be-cleaned target located on a to-be-cleaned area; and using a composite cleaning system to perform a composite cleaning step on the to-be-cleaned area of the object, wherein the composite cleaning step comprises using a laser cleaning device to perform a laser reactive cleaning step on the to-be-cleaned area of the object and using a gas or liquid cleaning device to perform a gas or liquid reactive cleaning step on the to-be-cleaned area of the object, thereby either the laser reactive cleaning step or the gas or liquid reactive cleaning step is assisted by the other to improve a cleaning effect of the to-be-cleaned target on the to-be-cleaned area.

Preferably, the composite cleaning step performs the laser reactive cleaning step and the gas or liquid reactive cleaning step on the to-be-cleaned area of the object simultaneously, sequentially or in reverse order.

Preferably, the laser reactive cleaning step and the gas or liquid reactive cleaning step are respectively selected from a group consisting of dry cleaning method and wet cleaning method.

Preferably, the composite cleaning step performs the laser reactive cleaning step on a partial area or an entire area of the to-be-cleaned area of the object that has the to-be-cleaned target, and performs the gas or liquid reactive cleaning step on the partial area or the entire area of the to-be-cleaned area of the object.

Preferably, the composite cleaning step, the laser cleaning device only performs the laser reactive cleaning step on the to-be-cleaned target on the to-be-cleaned area of the object.

Preferably, the gas or liquid reactive cleaning step performs a cleaning step selected from a group consisting of ozone cleaning method, hydrofluoric acid cleaning method and RCA cleaning agent method on the to-be-cleaned area of the object.

Preferably, the ozone cleaning method uses ozone-deionized water, ozone and/or hydrofluoric acid to clean the to-be-cleaned area of the object, the hydrofluoric acid cleaning method uses hydrofluoric acid to clean the to-be-cleaned area of the object, and the RCA cleaning agent method uses RCA cleaning agent to clean the to-be-cleaned area of the object.

Preferably, the gas or liquid cleaning device of the composite cleaning system further comprises an oscillating element for simultaneously oscillating the to-be-cleaned area of the object when performing the gas or liquid reactive cleaning step on the to-be-cleaned area of the object.

Preferably, the gas or liquid cleaning device of the composite cleaning system comprises a temperature control and adjustment element for performing control and adjustment of temperature when performing the gas or liquid reactive cleaning step on the to-be-cleaned area of the object.

Preferably, the composite cleaning system comprises a rotary worktable for performing the gas or liquid reactive cleaning step on the to-be-cleaned area of the object in a rotating state.

Preferably, the composite cleaning step of the composite cleaning system further comprises performing a grinding and polishing step on the to-be-cleaned area of the object before, between or after performing the laser reactive cleaning step and the gas or liquid reactive cleaning step.

Preferably, the composite cleaning step further comprises using a plasma device to provide a plasma to the to-be-cleaned area of the object before or after performing the grinding and polishing step.

Preferably, the composite cleaning step performs the grinding and polishing step on the to-be-cleaned area of the object in an environment containing ozone or ozone-deionized water.

Preferably, the composite cleaning step further comprises using a plasma device to provide a plasma to the to-be-cleaned area of the object.

Preferably, the plasma device is a remote plasma device, and the plasma is a remote plasma.

Preferably, the laser reactive cleaning step uses a laser beam to provide a pulse energy in a scanning manner to the to-be-cleaned area of the object.

Preferably, the laser reactive cleaning step causes the to-be-cleaned target on the to-be-cleaned area of the object to absorb the pulse energy and separate from the to-be-cleaned area of the object.

Preferably, the laser reactive cleaning step causes a liquid to absorb the pulse energy to generate an explosion pressure wave, thereby producing the cleaning effect on the to-be-cleaned target on the to-be-cleaned area of the object with assistance of the liquid.

Preferably, the laser reactive cleaning step provides the pulse energy to focus on a focal position adjacent to the to-be-cleaned target, thereby producing the cleaning effect on the to-be-cleaned target through a plasma shock wave formed at the focal position.

Preferably, the laser cleaning device provides the pulse energy in an adjustable manner to the to-be-cleaned area of the object through the laser beam in the laser reactive cleaning step.

Preferably, the to-be-cleaned target is selected from a group consisting of organic matters, polymers, metal impurities, particles, micro-rough structures and native oxide layers.

Preferably, the object is a crystal ingot, a wafer after cutting and before grinding and polishing, or a wafer after grinding and polishing.

Preferably, the object is a substrate, an object that has completed front-end-of-line (FEOL), an object that has completed back-end-of-line (BEOL) or a packaging object.

Preferably, the object is a semiconductor material selected from a group consisting of silicon, gallium arsenide, indium phosphide, gallium nitride and silicon carbide.

Preferably, the object is a low energy gap semiconductor (<1.5 eV) or a high energy gap semiconductor (>3.0 eV).

In order to achieve the aforementioned object, the disclosure further discloses a composite cleaning system for performing a composite cleaning step on a to-be-cleaned area of at least one object, comprising: a carrier for carrying the object, the object has at least one to-be-cleaned target located on the to-be-cleaned area of the object; a laser cleaning device for performing a laser reactive cleaning step on the to-be-cleaned area of the object; and a gas or liquid cleaning device for performing a gas or liquid reactive cleaning step on the to-be-cleaned area of the object, thereby either the laser reactive cleaning step or the gas or liquid reactive cleaning step is assisted by the other to improve a cleaning effect of the to-be-cleaned target on the to-be-cleaned area.

Preferably, the composite cleaning step performs the laser reactive cleaning step and the gas or liquid reactive cleaning step on the to-be-cleaned area of the object simultaneously, sequentially or in reverse order.

Preferably, the gas or liquid cleaning device performs a cleaning step selected from a group consisting of ozone cleaning method, hydrofluoric acid cleaning method and RCA cleaning agent method on the to-be-cleaned area of the object.

Preferably, the ozone cleaning method uses ozone-deionized water, ozone and/or hydrofluoric acid to clean the to-be-cleaned area of the object, the hydrofluoric acid cleaning method uses hydrofluoric acid to clean the to-be-cleaned area of the object, and the RCA cleaning agent method uses RCA cleaning agent to clean the to-be-cleaned area of the object.

Preferably, the gas or liquid cleaning device further comprises a tank, wherein the to-be-cleaned area of the object is performed with the gas or liquid reactive cleaning step in the tank.

Preferably, the gas or liquid cleaning device further comprises a tank, wherein a number of the object is plural, and the objects are placed in the tank at the same time to perform the gas or liquid reactive cleaning step.

Preferably, the gas or liquid cleaning device of the composite cleaning system further comprises an oscillating element for simultaneously oscillating the to-be-cleaned area of the object when performing the composite cleaning step on the to-be-cleaned area of the object.

Preferably, the gas or liquid cleaning device of the composite cleaning system comprises a temperature control and adjustment element for controlling and adjusting a temperature of the composite cleaning step when performing the composite cleaning step on the to-be-cleaned area of the object.

Preferably, the carrier is a rotary worktable for rotating the object, thereby enabling the gas or liquid cleaning device to perform the gas or liquid reactive cleaning step on the to-be-cleaned area of the object in a rotating state.

Preferably, the gas or liquid cleaning device comprises a gas or liquid supply source, and the gas or liquid supply source is selected from a group consisting of an ozone-deionized water generating device, an ozone generating device, a hydrofluoric acid supply device and an RCA cleaning agent supply device.

Preferably, the composite cleaning system further comprises performing a grinding and polishing step on the to-be-cleaned area of the object before, between or after performing the laser reactive cleaning step and the gas or liquid reactive cleaning step.

Preferably, the composite cleaning system further comprises a plasma device, wherein the plasma device provides a plasma to the to-be-cleaned area of the object before or after performing the grinding and polishing step.

Preferably, the composite cleaning step performs the grinding and polishing step on the to-be-cleaned area of the object in an environment containing ozone or ozone-deionized water.

Preferably, the composite cleaning step further comprises using a plasma device to provide a plasma to the to-be-cleaned area of the object.

Preferably, the plasma device is a remote plasma device, and the plasma is a remote plasma.

Preferably, the laser cleaning device generates a laser beam to provide a pulse energy in a scanning manner to the to-be-cleaned area of the object.

Preferably, the laser cleaning device causes the to-be-cleaned target on the to-be-cleaned area of the object to absorb the pulse energy and separate from the to-be-cleaned area of the object in the laser reactive cleaning step.

Preferably, the laser cleaning device causes a liquid to absorb the pulse energy to generate an explosion pressure wave in the laser reactive cleaning step, thereby producing the cleaning effect on the to-be-cleaned target on the to-be-cleaned area of the object with assistance of the liquid.

Preferably, the laser cleaning device provides the pulse energy to focus at a focal position that is a distance away from the to-be-cleaned target in the laser reactive cleaning step, thereby producing the cleaning effect on the to-be-cleaned target on the to-be-cleaned area through a plasma shock wave formed at the focal position.

Preferably, the laser cleaning device provides the pulse energy in an adjustable manner to the to-be-cleaned area of the object through the laser beam in the laser reactive cleaning step.

Preferably, the laser beam is a pulsed nanosecond laser with a wavelength of 1,064 nm.

Based on the above, the composite cleaning process and the composite cleaning system of the disclosure have the following advantages and features:

(1) By performing the laser reactive cleaning step and the gas or liquid reactive cleaning step to replace the conventional techniques of only cleaning objects with RCA cleaning agents and cleaning methods, the increasingly stringent process cleanliness requirements could be met.

(2) Using pulse energy with the gas or liquid reactive cleaning step could significantly reduce process steps, reduce water consumption, reduce chemical usage amounts and emissions, shorten process time and increase production capacity.

(3) Using pulse energy with the gas or liquid reactive cleaning step has good cleaning effects on various to-be-cleaned targets (such as organic matters, polymers, metal attachments, particles and native oxide layers), and a surface roughness is superior to traditional standard cleaning procedures.

(4) Using pulse energy with the gas or liquid reactive cleaning step, and also using a plasma device to provide a plasma, could further reduce a roughness of the to-be-cleaned area, remove small defects (crystal level), and achieve efficacies of high-temperature annealing and micro-growth epitaxy.

(5) The use of ozone (UV-Ozone) or ozone-deionized water (DI-Ozone) in the gas or liquid reactive cleaning step could combine or replace harmful chemicals in the traditional cleaning process, which could reduce water consumption, reduce chemical usage amounts and emissions, shorten process time and increase production capacity, and the cleaning effect and surface roughness are superior to traditional standard cleaning procedures.

(6) Using pulse energy to clean the to-be-cleaned area could cause the to-be-cleaned target located thereon to be ionized and move away after absorbing a high-energy light of a short pulse of a laser.

(7) By using pulse energy, the reactive cleaning ingredient of the gas or liquid reactive cleaning step could be ozone (gas or aqueous solution), and hydrofluoric acid (gas or aqueous solution), or RCA cleaning agent to meet cleanliness requirements of a process.

In order to enable the examiner to have a further understanding and recognition of the technical features of the disclosure, preferred embodiments in conjunction with detailed explanation are provided as follows.

### BRIEF DESCRIPTION OF THE DRAWINGS

FIG. 1 is a flowchart of a composite cleaning process according to a first embodiment of the disclosure.

FIG. 2 is a schematic diagram of a composite cleaning system according to the first embodiment of the disclosure, in which a laser cleaning device and a gas or liquid cleaning device are independent and different devices, wherein FIG. 2(A) shows performing a laser reactive cleaning step, and FIG. 2(B) shows performing a gas or liquid reactive cleaning step.

FIG. 3 is a schematic diagram of the composite cleaning system according to the first embodiment of the disclosure, in which the laser cleaning device and the gas or liquid cleaning device are integrated into a same device.

FIG. 4 is a flowchart of the composite cleaning process according to a second embodiment of the disclosure.

FIG. 5 is a schematic diagram of the composite cleaning system according to the second embodiment of the disclosure, wherein FIG. 5(A) shows performing a grinding and polishing step, FIG. 5(B) shows performing the laser reactive cleaning step, and FIG. 5(C) shows performing the gas or liquid reactive cleaning step.

FIG. 6 is a flowchart of the composite cleaning process according to a third embodiment of the disclosure, wherein FIG. 6(A) shows a first process mode, and FIG. 6(B) shows a second process mode.

FIG. 7 is a schematic diagram of the composite cleaning system according to the third embodiment of the disclosure, wherein FIG. 7(A) shows performing a step of providing plasma, FIG. 7(B) shows performing the grinding and polishing step, FIG. 7(C) shows performing the laser reactive cleaning step, and FIG. 7(D) shows performing the gas or liquid reactive cleaning step.

FIG. 8 is a structural diagram of the laser cleaning device of the disclosure in which a laser beam irradiates a to-be-cleaned target at an inclination angle.

### DETAILED DESCRIPTION OF THE DISCLOSURE

In order to understand the technical features, content and advantages of the disclosure and its achievable efficacies, the disclosure is described below in detail in conjunction with the figures, and in the form of embodiments, the figures used herein are only for a purpose of schematically supplementing the specification, and may not be true proportions and precise configurations after implementation of the disclosure; and therefore, relationship between the proportions and configurations of the attached figures should not be interpreted to limit the scope of the claims of the disclosure in actual implementation. In addition, in order to facilitate understanding, the same elements in the following embodiments are indicated by the same referenced numbers. And the size and proportions of the components shown in the drawings are for the purpose of explaining the components and their structures only and are not intending to be limiting.

Unless otherwise noted, all terms used in the whole descriptions and claims shall have their common meaning in the related field in the descriptions disclosed herein and in other special descriptions. Some terms used to describe in the present disclosure will be defined below or in other parts of the descriptions as an extra guidance for those skilled in the art to understand the descriptions of the present disclosure.

The terms such as “first”, “second”, “third”, “fourth” used in the descriptions are not indicating an order or sequence, and are not intending to limit the scope of the present disclosure. They are used only for differentiation of components or operations described by the same terms.

Moreover, the terms “comprising”, “including”, “having”, and “with” used in the descriptions are all open terms and have the meaning of “comprising but not limited to”.

A composite cleaning process and a composite cleaning system of the disclosure use at least two cleaning devices or more than two cleaning devices to perform at least two reactive cleaning steps or more than two reactive cleaning steps on various objects. A cleaning effect of the disclosure on a to-be-cleaned target located on a to-be-cleaned area of an object could be superior to that of the traditional single reactive cleaning step, and could exert an efficacy of assisting each other in cleaning, thereby meeting the increasingly stringent process cleanliness requirements. The composite cleaning process and the composite cleaning system of the disclosure could be used to remove various contaminants in a manufacturing process of various semiconductor objects, such as particles, metal impurities, organic pollutants, native oxide layers and micro-rough structures on a surface of an object, and could also be used to replace the plasma ashing technique used in the traditional photoresist stripping process. The term “cleaning” used in the disclosure generally refers to washing, cleansing and/or removing a to-be-cleaned target located on a to-be-cleaned area of an object, and even includes weakening or overcoming the van der Waals force or electrostatic force between the to-be-cleaned target and other substances (such as, objects attached to the to-be-cleaned target or objects composed of the to-be-cleaned target). The above-mentioned to-be-cleaned object is various objects, for example, various substrates, objects that have completed a front-end-of-line (FEOL), objects that have completed a back-end-of-line (BEOL) or packaging objects, etc., and structures formed on it are not limited. The object could also be, for example, a crystal ingot, a wafer after cutting and before grinding and polishing, or a wafer after grinding and polishing. For example, the object to which the disclosure is applicable could be a first-type semiconductor, a second-type semiconductor, or a third-type semiconductor, such as, but is not limited to, a semiconductor material selected from a group consisting of silicon, gallium arsenide, indium phosphide, gallium nitride and silicon carbide, and could be, for example, a low energy gap semiconductor (<1.5 eV) or a high energy gap semiconductor (>3.0 eV). It could be known from this that the to-be-cleaned target to which the disclosure is applicable could be a corresponding substance or corresponding substances or a corresponding layer of substances according to a type of the actual to-be-cleaned object and a processing process the object has subjected to before cleaning, for example, but is not limited to, selected from a group consisting of organic matters (such as photoresist residue), polymers (such as photoresist polymers), metal impurities (such as metal ions), particles, micro-rough structures and native oxide layers. The to-be-cleaned target is, for example, attached to the object or a part forming a structure of the object. However, it should be noted that although the disclosure enumerates the applicable objects and to-be-cleaned target as described above, it is not intended to limit the scope of protection claimed by the disclosure. Any objects and to-be-cleaned targets that could be cleaned through the composite cleaning process or the composite cleaning system of the disclosure fall within the scope of protection claimed by the disclosure.

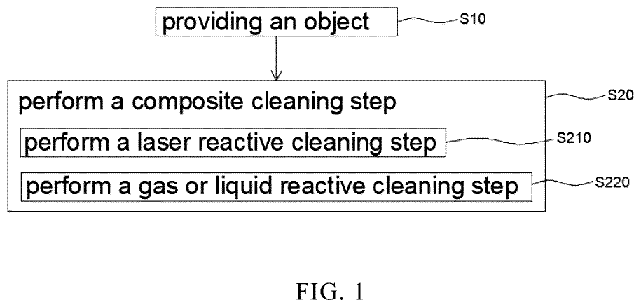

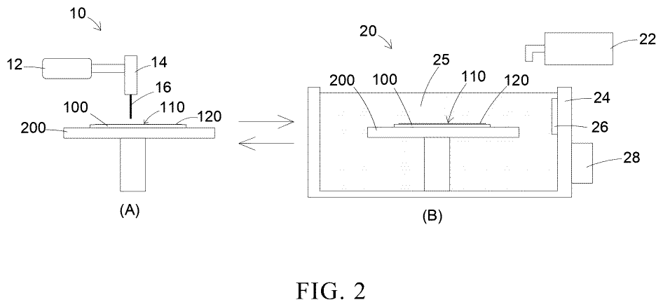

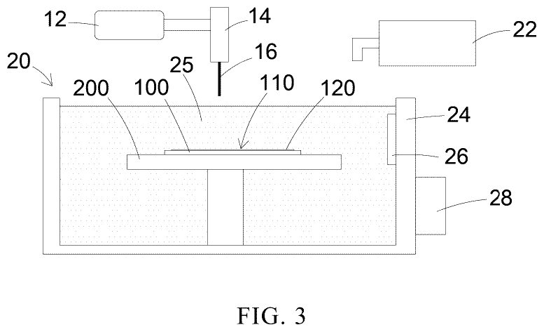

FIG. 1 is a flowchart of a composite cleaning process according to a first embodiment of the disclosure; FIG. 2 is a schematic diagram of a composite cleaning system according to the first embodiment of the disclosure, in which a laser cleaning device and a gas or liquid cleaning device are independent and different devices, wherein FIG. 2(A) shows performing a laser reactive cleaning step, and FIG. 2(B) shows performing a gas or liquid reactive cleaning step; and FIG. 3 is a schematic diagram of the composite cleaning system according to the first embodiment of the disclosure, in which the laser cleaning device and the gas or liquid cleaning device are integrated into a same device. Please refer to FIGS. 1, 2 and 3, the composite cleaning process of the disclosure at least comprises following steps of: a step of providing an object 100 (S10), wherein the object 100 has at least one to-be-cleaned target 120 located on a to-be-cleaned area 110; and using the composite cleaning system to perform a composite cleaning step (S20) on the to-be-cleaned area 110 of the object 100. The composite cleaning step (S20) comprises using a laser cleaning device 10 to perform a laser reactive cleaning step (S210) on the to-be-cleaned area 110 of the object 100; and using a gas or liquid cleaning device 20 to perform a gas or liquid reactive cleaning step (S220) on the to-be-cleaned area 110 of the object 100. One feature of the disclosure is that, either the laser reactive cleaning step (S210) or the gas or liquid reactive cleaning step (S220) is assisted by the other to improve a cleaning effect of the to-be-cleaned target 120 on the to-be-cleaned area 110.

Please continue to refer to FIGS. 1, 2 and 3. The composite cleaning system of the disclosure at least comprises the laser cleaning device 10 for providing pulse energy (such as one laser beam 16 or a plurality of laser beams 16) and the gas or liquid cleaning device 20 for providing reactive cleaning ingredients (such as one reactive gas and/or liquid or reactive gases and/or liquids), wherein the composite cleaning system optionally comprises a carrier 200 for carrying the at least one to-be-cleaned object 100, a number of the object 100 could be one or more than one, wherein the object 100 has the at least one to-be-cleaned target 120 located on the to-be-cleaned area 110. The laser cleaning device 10 comprises, for example, a laser beam generator 12 and a lens set 14. Wherein the laser beam generator 12 generates one laser beam 16 or a plurality of laser beams 16 irradiating the to-be-cleaned object 100 through the lens set 14 to perform the laser reactive cleaning step (S210). Wherein the lens set 14 could be optionally omitted or integrated into the laser beam generator 12. The gas or liquid cleaning device 20 comprises, for example, a gas or liquid supply source 22 for supplying reactive cleaning ingredients (e.g., reactive gases and/or liquids) to the to-be-cleaned object 100, and the gas or liquid cleaning device 20 further optionally comprises a tank 24, which is, for example, a hollow container. Thereby the to-be-cleaned object 100 or the to-be-cleaned objects 100 could be placed in the tank 24 at the same time, and reactive cleaning ingredients (such as a liquid 25) are supplied into the tank 24 to perform the gas or liquid reactive cleaning step (S220). The gas or liquid supply source 22 of the gas or liquid cleaning device 20 could optionally use conventional commercial products, such as, but are not limited to, selected from a group consisting of an ozone-deionized water generating device, an ozone generating device, a hydrofluoric acid supply device and an RCA cleaning agent supply device for supplying one reactive gas and/or liquid or reactive gases and/or liquids. The ozone-deionized water generating device is used to supply ozone-deionized water conventionally used for cleaning. The ozone generating device is used to supply ozone gas conventionally used for cleaning. The hydrofluoric acid supply device is used to supply gaseous or liquid hydrofluoric acid conventionally used for cleaning. The RCA cleaning agent supply device is used to supply RCA cleaning agents conventionally used for cleaning, such as, but are not limited to, SC-1 cleaning formula and SC-2 cleaning formula.

The gas or liquid cleaning device 20 could optionally further comprise an oscillating element 26, such as an ultrasonic oscillating element, to enhance a cleaning effect of the gas or liquid reactive cleaning step (S220) by generating ultrasonic oscillations. In addition, the gas or liquid cleaning device 20 could optionally further comprise a temperature control and adjustment element 28, which could be, for example, a conventional commercial temperature controller, used to perform temperature control and adjustment when performing the gas or liquid reactive cleaning step (S220) on the object 100. For example, a temperature of the gas or liquid reactive cleaning step (S220) is adjusted immediately according to reactive cleaning ingredients provided by the gas or liquid reactive cleaning step (S220) and a temperature required for cleaning reaction for the to-be-cleaned target 120. Wherein the to-be-cleaned object 100 could also be optionally carried on the carrier 200 and placed in the tank 24 through movement of the carrier 200. The laser cleaning device 10 and the gas or liquid cleaning device 20 could be independent disposed (e.g., as shown in FIG. 2) or integrated with each other (e.g., as shown in FIG. 3), thereby the disclosure is capable of optionally performing the laser reactive cleaning step (S210) and the gas or liquid reactive cleaning step (S220) in the different devices or the same device.

In the composite cleaning process of the disclosure, both the laser reactive cleaning step (S210) and the gas or liquid cleaning device 20 could be selected from a group consisting of dry cleaning method and wet cleaning method. The laser cleaning device 10 of the disclosure generates the laser beam 16 or the laser beams 16 in a scouldning manner to directly or indirectly provide pulse energy (such as pulse reactive energy) to the to-be-cleaned area 110 of the object 100, thereby performing the laser reactive cleaning step (S210) on the to-be-cleaned area 110 of the object 100, wherein the laser reactive cleaning step (S210) is, for example, selected from a group consisting of dry cleaning method and wet cleaning method, in order to achieve an effect of dry or wet cleaning of the to-be-cleaned area 110.

In detail, the laser cleaning device 10 generates the laser beam 16 through the laser beam generator 12 to optionally provide fixed or adjustable pulse energy. For example, the laser cleaning device 10 could optionally adjust scanning speed, pulse width, pulse output period, wavelength, repetition frequency, incident angle, penetration depth and/or thermal diffusion length of the laser beam 16 to provide adjustable pulse energy. Generally, the shorter a wavelength of the laser beam 16, the higher an energy absorbed by the to-be-cleaned target 120, and the faster a heating rate. In addition, the disclosure could also provide optional cleaning efficacies through the laser beam 16, for example, only removing the to-be-cleaned target 120 on the to-be-cleaned area 110, while retaining remaining structures or substances on the to-be-cleaned area 110. The laser beam 16 provided by the laser cleaning device 10 is, for example, but not limited to, a pulsed nanosecond laser. If a pulse width of the laser beam 16 is greater than the nanosecond (ns) level, although an attack performance is stronger, a material selectivity is weaker. If a pulse width of the laser beam 16 is less than the nanosecond (ns) level, it is cold ablation and its material specificity is low. A pulse width of the laser beam 16 used in the disclosure is preferably in the nanosecond (ns) level, which could have heating and cooling frequencies higher than other levels of pulse width, and could have better material specificity. For example, the laser beam generator 12 of the laser cleaning device 10 could optionally use conventional commercial products, such as, but are not limited to, Nd:YAG pulse laser source, Nd:YVO₄ pulse laser source or KrF pulse laser source. Taking the Nd:YAG pulse laser source as an example, its wavelength is about 1,064 nm, frequency is about 20 kHz, and pulse width is about 150 ns, but are not limited thereto. A wavelength generated by the laser beam generator 12 could also be, for example, 266 nm or 532 nm. For example, a moving speed of the laser beam 16 ranges from about 10 mm/sec to about 1,000 mm/sec, a wavelength range of the laser beam 16 is preferably from about 266 nm to about 1,600 nm, a pulse width is about less than 1,000 ns, a repetition frequency range is about 30 Hz to about 10 MHz, a pulse energy (E) range is, for example, about 0.1 J to about 10,000 J, and a spot diameter range, for example, is about 0.5 μm to about 100 mm.

Reactive cleaning ingredients provided by the gas or liquid cleaning device 20 of the disclosure could be, for example, reactive gases and/or liquids, such as including ozone gas (UV-Ozone) and/or ozone-deionized water (DI-Ozone), or even further optionally comprise hydrofluoric acid, thereby enhancing a cleaning effect, reducing or replacing harmful chemicals used in traditional cleaning processes, or reducing adverse effects that could be on the object 100. Wherein the reactive cleaning ingredients are optionally, for example, ozone (03) in gas form, which could be used directly or used in combination with other gases (such as hydrofluoric acid) or liquids (such as hydrofluoric acid solution or RCA cleaning agent), in order to perform a cleaning step on the to-be-cleaned area 110. Ozone could be formed or generated in various ways, including provided by conventional commercial ozone generating devices, in which, for example, ozone is produced from oxygen through energy fields (such as ultraviolet light, plasma or ion fields). In addition, the reactive cleaning ingredient of the disclosure could also be optionally an aqueous solution containing ozone (commonly known as ozone-deionized water, DI-Ozone), which could be used directly or in combination with other gases (such as hydrofluoric acid) or liquids (such as hydrofluoric acid solution or RCA cleaning agent) to perform a cleaning step on the to-be-cleaned area 110, wherein a concentration of ozone in the DI aqueous solution is from about 1 ppm to about 300 ppm. For example, the gas or liquid reactive cleaning step (S220) of the disclosure could use ozone-deionized water with a concentration of about 30 ppm and a flow rate of about 2 lpm (liters per minute) to clean the to-be-cleaned target 120 for about 1 hour. In addition, the DI aqueous solution could also contain ozone cleaning auxiliaries, such as carbonate and bicarbonate anions, and organic acids, such as formic acid, oxalic acid, acetic acid, and glycolic acid. For example, in a manufacturing process of removing photoresist by using plasma etching method and SPM cleaning solution in the conventional techniques, after most (about 99%) of photoresist is removed by plasma, a remaining 1% of photoresist residues are removed by RCA cleaning agent method. However, the composite cleaning step (S20) of the disclosure could perform the laser reactive cleaning step (S210) and the gas or liquid reactive cleaning step (S220) to replace the RCA cleaning agent method of the conventional techniques, or to replace parts of cleaning formulas in the RCA cleaning agent method, for example, the disclosure could replace H₂O₂ in the SC-1 cleaning formula of the RCA cleaning agent method of the conventional techniques with ozone-deionized water (DI-Ozone), alternatively, for example, using dilute hydrofluoric acid (DHF) combined with ozone-deionized water (e.g., room temperature) to replace the SPM cleaning solution (H₂SO₄/H₂O₂)/H₂O, i.e., Piranha cleaning solution) that requires high temperature (about 100 degrees Celsius to about 130 degrees Celsius) in order to remove a remaining 1% of photoresist residues. Furthermore, the disclosure could further replace the above-mentioned plasma etching method by, for example, the laser reactive cleaning step (S210), thereby removing most (about 99%) of the photoresist. A volume ratio of hydrofluoric acid to ozone-deionized water ranges from about 1:1 to about 10:1, for example.

In the first embodiment, the disclosure, for example, performs the laser reactive cleaning step (S210) and the gas or liquid reactive cleaning step (S220) on the to-be-cleaned area 110 of the object 100 simultaneously, sequentially or in reverse order, so as to achieve an effect of auxiliary cleaning of the to-be-cleaned target 120. As mentioned above, the laser cleaning device 10 and the gas or liquid cleaning device 20 of the disclosure could be different independent devices or integrated into a same device, thereby the disclosure could optionally perform the laser reactive cleaning step (S210) and the gas or liquid reactive cleaning step (S220) in the different devices or the same device.

In a first mode of the first embodiment, the disclosure, for example, first uses the laser cleaning device 10 to generate the laser beam 16 in a scanning manner to directly or indirectly provide pulse energy to the to-be-cleaned area 110 of the object 100, thereby performing the laser reactive cleaning step (S210) on the to-be-cleaned area 110 of the object 100. Then, the gas or liquid cleaning device 20 is used to perform the gas or liquid reactive cleaning step (S220) on the to-be-cleaned area 110 that has been cleaned by the laser reactive cleaning step (S210). Since the laser cleaning device 10 has performed the laser reactive cleaning step (S210) on the to-be-cleaned area 110 of the object 100, the disclosure could enhance a cleaning effect of the gas or liquid reactive cleaning step (S220) on the to-be-cleaned target 120 of the to-be-cleaned area 110 with an assistance of the laser reactive cleaning step (S210).

In a second mode of the first embodiment, the disclosure, for example, first uses the gas or liquid cleaning device 20 to perform the gas or liquid reactive cleaning step (S220) on the to-be-cleaned area 110; then, uses the laser cleaning device 10 to generate the laser beam 16 in a scanning manner to directly or indirectly provide pulse energy to the to-be-cleaned area 110 of the object 100, thereby performing the laser reactive cleaning step (S210) on the to-be-cleaned area 110 that has been cleaned by the gas or liquid reactive cleaning step (S220). Since the gas or liquid cleaning device 20 has performed the gas or liquid reactive cleaning step (S220) on the to-be-cleaned area 110 of the object 100, the disclosure could enhance a cleaning effect of the laser reactive cleaning step (S210) on the to-be-cleaned target 120 of the to-be-cleaned area 110 with an assistance of the gas or liquid reactive cleaning step (S220).

In a third mode of the first embodiment, the disclosure uses, for example, the laser cleaning device 10 and the gas or liquid cleaning device 20 to simultaneously perform the laser reactive cleaning step (S210) and the gas or liquid reactive cleaning step (S220) on the to-be-cleaned area 110 of the object 100. Since the laser cleaning device 10 and the gas or liquid cleaning device 20 simultaneously perform the laser reactive cleaning step (S210) and the gas or liquid reactive cleaning step (S220) on the to-be-cleaned area 110 of the object 100, the laser reactive cleaning step (S210) and the gas or liquid reactive cleaning step (S220) could assist each other to enhance a cleaning effect of the to-be-cleaned target 120 of the to-be-cleaned area 110.

In the composite cleaning process of the disclosure, the object 100 is, for example, carried on the carrier 200 of the composite cleaning system. The carrier 200 could be various fixed-point or mobile worktables, and could optionally be various fixed or rotary worktables. There is no limitation on configuration or type of the carrier 200, which could be decided according to a type of the to-be-cleaned object 100 and configuration or type of the laser cleaning device 10 and the gas or liquid cleaning device 20. Taking the rotary worktable as an example, the carrier 200 could be selected from a group consisting of horizontal, vertical and tilting worktables, such as conventional commercial rotating platforms used in grinding and polishing steps (such as mechanical grinding and polishing or chemical-mechanical polishing (CMP)). Alternatively, the gas or liquid cleaning device 20 is, for example, a conventional commercial photoresist cleaning machine (such as spray solvent tool (SST)), and the carrier 200 is a rotary carrier rack of the SST machine. Thereby the gas or liquid reactive cleaning step (S220) could be performed simultaneously on the to-be-cleaned area 110 of the object 100 in a rotating state.

In addition, the composite cleaning step (S20) of the disclosure could optionally perform the laser reactive cleaning step (S210) on a partial area or an entire area of the to-be-cleaned area 110 of the object 100 that has the to-be-cleaned target 120, and optionally perform the gas or liquid reactive cleaning step (S220) on a partial area or an entire area of the to-be-cleaned area 110 of the object 100. In other words, in the disclosure, although cleaning areas cleaned by the laser reactive cleaning step (S210) and the gas or liquid reactive cleaning step (S220) preferably overlap, they are not limited to being exactly the same, as long as auxiliary cleaning effects could be provided, it falls within the scope of protection claimed by the disclosure. For example, in the composite cleaning step (S20) of the disclosure, the laser cleaning device 10 could also perform the laser reactive cleaning step (S210) only on the to-be-cleaned target 120 on the to-be-cleaned area 110, and the gas or liquid reactive cleaning step (S220) is performed on the to-be-cleaned area 110 including the to-be-cleaned target 120.

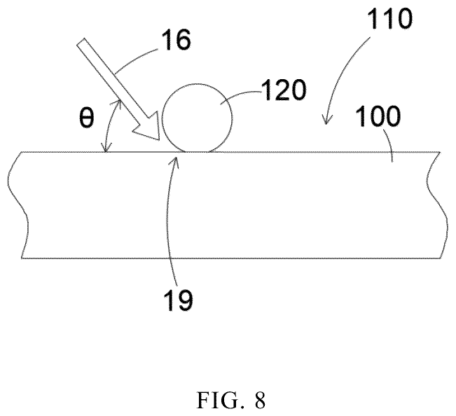

The laser cleaning device 10 of the disclosure could perform the laser reactive cleaning step (S210) by, for example, etching cleaning method, liquid-assisted laser cleaning method, and/or laser shock wave cleaning method. Taking the etching cleaning method as an example, when performing the laser reactive cleaning step (S210) of the composite cleaning process, the object 100 to which the disclosure is applicable is not limited to being located in an air environment, regardless of whether the to-be-cleaned object 100 is located in a liquid environment or in a gas environment, the disclosure could use the laser beam 16 generated by the laser cleaning device 10 to directly irradiate (e.g., focusing) the to-be-cleaned target 120 of the object 100, so that the to-be-cleaned target 120 of the to-be-cleaned area 110 directly absorbs pulse energy of the laser beam 16 (e.g., short pulse) and then generates ionization and moves away from the to-be-cleaned area 110 and/or, for example, weakens a bond (van der Waals bond) strength between the to-be-cleaned target 120 and the object 100, or causes defects or instability, thereby contributing to an overall cleaning effect of the composite cleaning step (S20) on the to-be-cleaned area 110. Wherein, the liquid or gas could be the same as or different from the reactive cleaning ingredient used in the gas or liquid reactive cleaning step (S220). In addition, in the etching cleaning method, the laser beam 16 could be optionally irradiated directly at a shadow interface 19 (as shown in FIG. 8) between the to-be-cleaned target 120 (for example, metal impurities or particles) and the object 100. Due to differences in material properties (e.g., thermal expansion coefficient) between the to-be-cleaned target 120 and the object 100, stress will be generated at the shadow interface 19, which helps to separate the to-be-cleaned target 120 from the object 100. Although the laser beam 16 provided by the disclosure could be directly irradiated directly above the to-be-cleaned target 120, that is, an irradiation direction of the laser beam 16 is perpendicular to the object 100, it is not limited thereto. For example, as shown in FIG. 8, in order to enable the shadow interface 19 between the to-be-cleaned target 120 and the object 100 to effectively absorb pulse energy of the laser beam 16 (e.g., short pulse), the laser beam 16 could also optionally irradiate the shadow interface 19 between the to-be-cleaned target 120 (e.g., metal impurities or particles) and the object 100 at an inclination angle θ to prevent a top of the to-be-cleaned target 120 from blocking the laser beam 16 directly irradiating the shadow interface 19. Alternatively, in the etching cleaning method, the laser beam 16 could also irradiate the to-be-cleaned target 120, for example, on a reverse side, that is, the laser beam 16 preferably irradiates and penetrates the object 100 (for example, with non-light absorption substrate), and then irradiates to reach a bottom of the to-be-cleaned target 120, such as the shadow interface 19 between the to-be-cleaned target 120 and the object 100. Wherein an irradiation direction of the laser beam 16 is, for example, different from an extension direction of the to-be-cleaned target 120, for example, non-perpendicular to the object 100. In other words, the above-mentioned inclination angle θ ranges from about 89 degrees to about 179 degrees.

Taking the liquid-assisted laser cleaning method as an example (please refer to FIG. 2 as well), if the to-be-cleaned object 100 is located in a liquid 25, the disclosure could, for example, make the liquid 25 absorb pulse (such as short pulse) reactive energy of the laser beam 16, thereby producing a cleaning effect on the to-be-cleaned target 120 on the to-be-cleaned area 110 of the object 100 through an assistance of the liquid 25. For example, the laser beam 16 provided by the disclosure could be directly focused to irradiate the liquid 25 (such as water or alcohol (such as isopropyl alcohol)) adjacent to (or called nearby or around) the to-be-cleaned target 120, explosion pressure wave generated by explosive evaporation of the liquid 25 due to increase in temperature (overheating) could reduce or eliminate a bonding force between the to-be-cleaned target 120 and the object 100, so a cleaning effect could be achieved. Moreover, the disclosure could further reduce generation of thermal stress by heating the liquid 25. The liquid 25 could be the same as or different from the reactive cleaning ingredient used in the gas or liquid reactive cleaning step (S220). Taking the liquid-assisted laser cleaning method to remove gold and tungsten particles (particle size is about m level) on a surface of a silicon substrate as an example, the laser beam generator 12 could use a KrF pulse laser source, pulse width of the laser beam 16 is about 30 ns, repetition frequency range is about 100 Hz, pulse energy is about 0.3 J/cm², and wavelength is about 248 nm. Taking the liquid-assisted laser cleaning method to remove aluminum oxide particles (Al₂O₃, particle size about 60 nm) on a surface of a silicon substrate as an example, the laser beam generator 12 could use an Nd:YAG pulse laser source, pulse width of the laser beam 16 is about 7 ns, repetition frequency range is about 8 Hz, pulse energy is about 0.17 J/cm², and wavelength is about 532 nm.

Taking the laser shock wave cleaning method as an example, the disclosure could, for example, focus pulse energy provided by the laser beam 16 at a focal position that is a distance away from the to-be-cleaned target 120 (for example, adjacent to or referred to as nearby or around), wherein the object 100 could, for example, be located in an air environment or a gaseous environment, so that gas molecules at the focal position are ionized to form rapidly expanding plasma to generate a plasma shock wave, which could be used to remove the to-be-cleaned target 120. Wherein a gas in a gaseous environment could be the same as or different from the reactive cleaning ingredient used in the gas or liquid reactive cleaning step (S220). In short, the disclosure could be performed by the laser beam 16 directly contacting (focusing) the to-be-cleaned target 120 or the laser beam 16 indirectly contacting (focusing) the to-be-cleaned target 120, and whether it is in a liquid environment or in a gaseous environment, performing the laser reactive cleaning step (S210) on the to-be-cleaned target 120 will contribute to a cleaning effect of the composite cleaning step (S20) on the to-be-cleaned area 110. Taking the etching cleaning method or the laser shock wave cleaning method to remove silicon dioxide particles (such as fused quartz particles, with a particle size of about 5 m) on a surface of a silicon substrate as an example, the laser beam generator 12 could use a KrF pulse laser source, pulse width of the laser beam 16 is about 15 ns, repetition frequency range is about 30 Hz, pulse energy is about 60 mJ/cm², and wavelength is about 248 nm. Taking the etching cleaning method or the laser shock wave cleaning method to remove copper particles (particle size is about 1 m) on a surface of a silicon substrate as an example, the laser beam generator 12 could use an Nd:YAG pulse laser source, pulse width of the laser beam 16 is about 10 ns, repetition frequency range is about 10 kHz, pulse energy is about 0.18/0.46 mJ/cm², and wavelength is about 266/352 nm. Taking the etching cleaning method or the laser shock wave cleaning method to remove gold layers (thickness is about 48 nm) deposited on a surface of a silicon substrate as an example, the laser beam generator 12 could use an Nd:YAG pulse laser source, pulse width of the laser beam 16 is approximately 100 ns, repetition frequency range is approximately 2 kHz, pulse energy is approximately 10 mJ/cm², and wavelength is approximately 1,064 nm. Taking the etching cleaning method or the laser shock wave cleaning method to remove polystyrene latex nanoparticles (particle size is about 300 nm) on a surface of a silicon substrate as an example, the laser beam generator 12 could use an Nd:YAG pulse laser source, pulse width of the laser beam 16 is about 6 ns, pulse energy is about 100-600 mJ/cm², and wavelength is about 1,064 nm.

The gas or liquid reactive cleaning step (S220) of the disclosure provides reactive cleaning ingredients (e.g., reactive gases and/or liquids) for performing a group consisting of dry cleaning method and wet cleaning method, wherein the gas or liquid reactive cleaning step (S220) is, for example, a cleaning step selected from a group consisting of ozone cleaning method, hydrofluoric acid cleaning method and RCA cleaning agent method performing on the to-be-cleaned area 110 of the object 100. For example, the above-mentioned ozone cleaning method could be, for example, a dry cleaning method using ozone gas (UV-Ozone) and/or a wet cleaning method using ozone-deionized water (DI-Ozone), a concentration of ozone in the DI aqueous solution ranges from about 1 ppm to about 300 ppm, and a cleaning temperature range is about 0 degrees Celsius to about 60 degrees Celsius. The above-mentioned hydrofluoric acid cleaning method could be, for example, a dry cleaning method using hydrofluoric acid (HF) gas and/or a wet cleaning method using hydrofluoric acid liquid (such as diluted hydrofluoric acid liquid), wherein a volume ratio of HF:H₂O ranges from about 1:2 to about 1:10, and a cleaning temperature ranges from about 20 degrees Celsius to about 25 degrees Celsius. Hydrofluoric acid has a property of dissolving silicon dioxide, so it could remove oxide layers (such as the native oxide layer) generated on a surface of a silicon substrate, and at the same time, particles and metal impurities adsorbed on the oxide layers are removed. Moreover, while removing the oxide layers, silicon hydrogen bonds could also be formed on a surface of a silicon substrate to make a silicon surface hydrophobic. The RCA cleaning agent method, for example, uses SC-1 and SC-2 cleaning formulas, and could even optionally include using SPM cleaning solutions (such as SC-3 cleaning formula), wherein the SC-1 cleaning formula is, for example, NH₄OH/H₂O₂/H₂O, volume ratio range is about 1:1:5 to about 1:2:7, cleaning time range is about 10 minutes to about 20 minutes, cleaning temperature range is about 65 degrees Celsius to about 80 degrees Celsius, the SC-1 cleaning formula is preferably used for alkaline oxidation to remove particles on silicon substrates, and could oxidize and remove a small amount of organic matters (such as residual photoresist) and metal pollutants such as Au, Ag, Cu, Ni, Cd, Zn, Ca, Cr on a surface, wherein cleaning temperature controlled below 80 degrees Celsius helps to reduce losses caused by volatilization of ammonia and hydrogen peroxide; the SC-2 cleaning formula is, for example, HCl/H₂O/H₂O, with a volume ratio ranging from about 1:1:5 to about 1:2:8, cleaning time range is about 10 minutes to about 20 minutes, cleaning temperature range is about 75 degrees Celsius to about 85 degrees Celsius; the SC-3 cleaning formula is, for example, H₂SO₄/H₂O₂/H₂O, volume ratio is about 5:1:1, cleaning temperature range is about 120 degrees Celsius to about 280 degrees Celsius. The SC-3 cleaning formula has a high oxidizing ability, capable of oxidizing metals and dissolving them in a cleaning solution, and capable of oxidizing organic matters to generate CO₂ and H₂O. The SC-3 cleaning formula could clean organic contamination and some metal impurities on a surface of a silicon substrate. However, when the organic contamination is particularly severe, it will carbonize the organic matters and make it difficult to remove.

Taking cleaning of substrates, FEOL, BEOL and packaged objects as an example, the disclosure performs the laser reactive cleaning step (S210) and the gas or liquid reactive cleaning step (S220) to replace the conventional techniques of only using RCA cleaning agent method to clean the to-be-cleaned target 120. Wherein the gas or liquid reactive cleaning step (S220) of the composite cleaning step (S20) of the disclosure could optionally use any one of or any combination of ozone cleaning method, hydrofluoric acid cleaning method and RCA cleaning agent method.

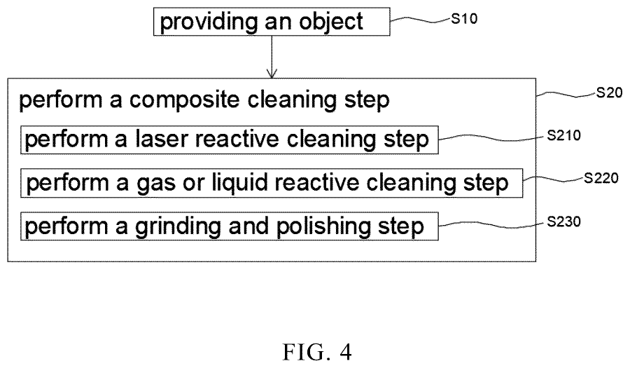

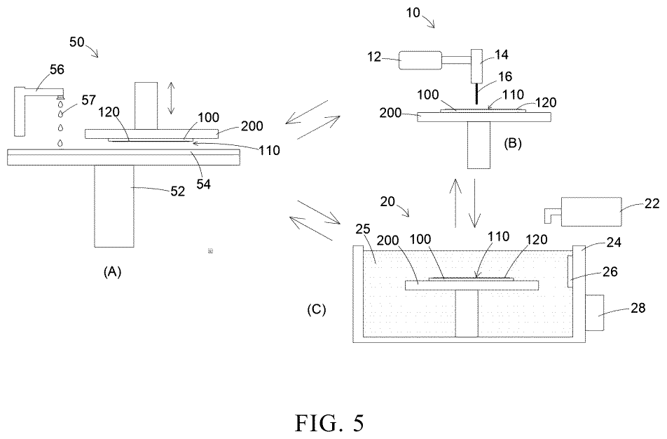

FIG. 4 is a flowchart of the composite cleaning process according to a second embodiment of the disclosure; and FIG. 5 is a schematic diagram of the composite cleaning system according to the second embodiment of the disclosure, FIG. 5(A) shows performing a grinding and polishing step, FIG. 5(B) shows performing the laser reactive cleaning step, FIG. 5(C) shows performing the gas or liquid reactive cleaning step. As shown in FIGS. 4 and 5, in the second embodiment of the disclosure, in addition to the devices shown in the first embodiment, the composite cleaning system of the disclosure further comprises a grinding and polishing device 50. The composite cleaning step (S20) of the disclosure optionally further comprises using the grinding and polishing device 50 (such as mechanical grinding and polishing device or chemical-mechanical polishing device) to perform a grinding and polishing step (S230) on the to-be-cleaned area 110 of the object 100, and then perform the laser reactive cleaning step (S210) and the gas or liquid reactive cleaning step (S220) on the to-be-cleaned area 110 of the object 100 simultaneously, sequentially or in reverse order. Taking the grinding and polishing device 50 as a chemical-mechanical polishing device an example, a structure of the grinding and polishing device 50 comprises, for example, a rotating platform 52, a polishing pad 54 and a polishing slurry supply source 56. The rotating platform 52 is used to drive the polishing pad 54 to rotate relative to the object 100 on the carrier 200, and the polishing slurry supply source 56 is used to supply a slurry 57 between the polishing pad 54 and the object 100, thereby the grinding and polishing step (S230) could be performed on the object 100. However, the disclosure is not limited thereto, the disclosure could also optionally perform the grinding and polishing step (S230) on the to-be-cleaned area 110 of the object 100 before, between or after performing the laser reactive cleaning step (S210) and the gas or liquid reactive cleaning step (S220).

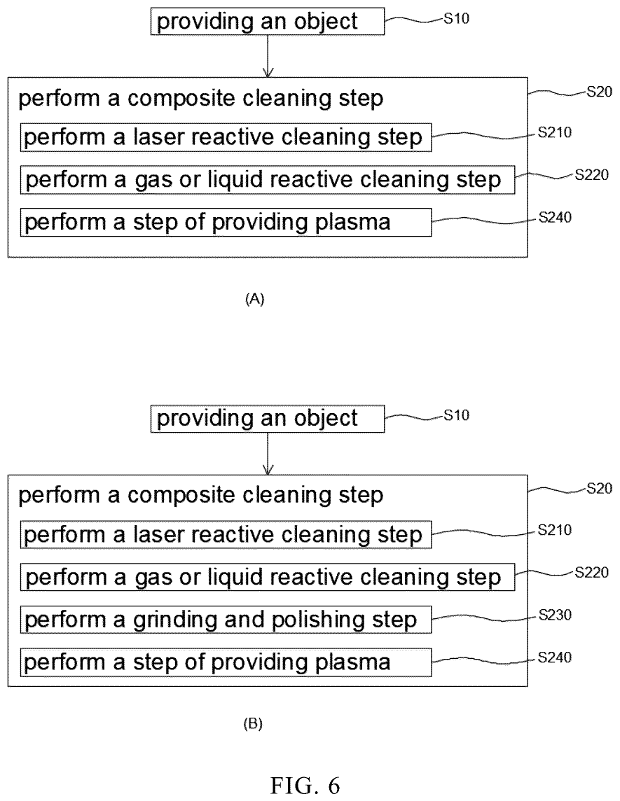

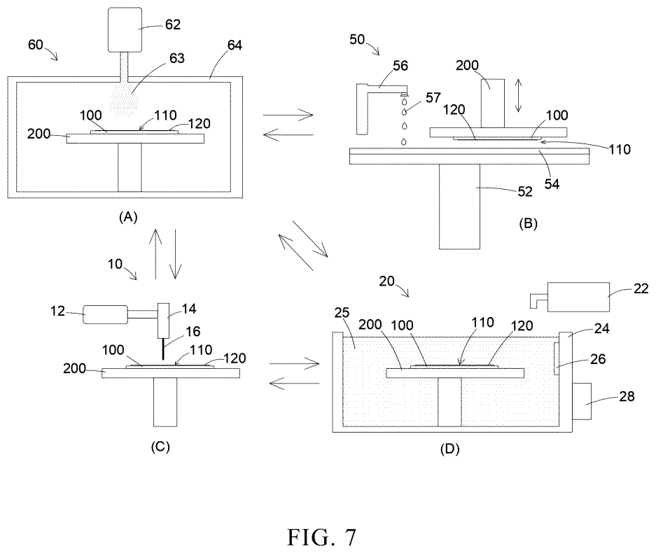

FIG. 6 is a flowchart of the composite cleaning process according to a third embodiment of the disclosure, FIG. 6(A) shows a first process mode, FIG. 6(B) shows a second process mode; and FIG. 7 is a schematic diagram of the composite cleaning system according to the third embodiment of the disclosure, FIG. 7(A) shows performing a step of providing plasma, FIG. 7(B) shows performing the grinding and polishing step, FIG. 7(C) shows performing the laser reactive cleaning step, FIG. 7(D) shows performing the gas or liquid reactive cleaning step. As shown in FIGS. 6 and 7, in the third embodiment of the disclosure, in addition to the devices shown in the second embodiment, the composite cleaning system of the disclosure further comprises a plasma device 60, such as comprising a plasma source 62 and a cavity 64, wherein the cavity 64 is used to place the object 100, and the plasma source 62 is used to provide a plasma 63 to the to-be-cleaned area 110 of the object 100 in the composite cleaning step S20. Wherein the plasma device 60 is, for example, a remote plasma device, and the plasma 63 is, for example, a remote plasma, but are not limited thereto. As shown in FIG. 6 (A), FIG. 7 (B), FIG. 7 (C) and FIG. 7 (D), before or after performing the laser reactive cleaning step S210 or the gas or liquid reactive cleaning step (S220), the plasma device 60 of the disclosure could, for example, perform a step of providing plasma (S240) on the to-be-cleaned area 110 of the object 100. In addition, as shown in FIG. 6(B) and FIG. 7(A) to FIG. 7(D), the composite cleaning step (S20) of the disclosure optionally further comprises using the plasma device 60 to perform the step of providing plasma (S240) before or after performing the grinding and polishing step (S230), for example, after performing the grinding and polishing step (S230), in order to provide the plasma 63 to the to-be-cleaned area 110 of the object 100, so that the to-be-cleaned area 110 of the object 100 has efficacies, for example, roughness reduction, small defect removal (crystal level), high temperature annealing and micro-growth epitaxy, and then performing the laser reactive cleaning step (S210) and the gas or liquid reactive cleaning step (S220) on the to-be-cleaned area 110 of the object 100 simultaneously, sequentially or in reverse order. In the disclosure, an order (for example, directions indicated by arrows in the figures) in which the laser cleaning device 10, the gas or liquid cleaning device 20, the grinding and polishing device 50 and the plasma device 60 being used and a combination method could be adjusted accordingly based on actual applications, for example, based on a mode (i.e., a previous process undergone before performing the composite cleaning process of the disclosure) of the to-be-cleaned object 100. For example, the disclosure could use a conventional commercial grinding slurry (such as adding alumina, silica, spinel, plutonium trioxide and zirconium oxide) to perform the grinding and polishing step (S230), or the disclosure could also perform the grinding and polishing step (S230) on the to-be-cleaned area 110 of the object 100 in an environment containing ozone or ozone-deionized water. For example, ozone or ozone-deionized water is dissolved in the above-mentioned conventional commercial grinding slurry, so that the gas or liquid reactive cleaning step (S220) and the grinding and polishing step (S230) (such as mechanical grinding and polishing or chemical-mechanical polishing (CMP)) could be performed simultaneously, wherein a concentration of ozone in the DI aqueous solution ranges from about 1 ppm to about 300 ppm, depending on the to-be-cleaned target 120. In addition, the DI aqueous solution could also contain ozone cleaning auxiliaries, such as carbonate and bicarbonate anions, and organic acids, such as formic acid, oxalic acid, acetic acid, and glycolic acid.

In the disclosure, when the composite cleaning system is used to perform the different cleaning steps (such as performing the laser reactive cleaning step (S210), performing the gas or liquid reactive cleaning step (S220), performing the grinding and polishing step (S230) and performing the step of providing plasma (S240)) of the composite cleaning process, the carrier 200 used to carry the object 100 could be the same one or replaced with a different one. If it is the same one, it could be, for example, using a conveying system (not shown in the figures) such as a conveyor belt or a robotic arm to move the carrier 200 and the object 100 the carrier 200 carries from a previous cleaning device to a next cleaning device in order to perform a cleaning step. If it is a different one, it could be, for example, using a conveying system (not shown in the figures) such as a conveyor belt or a robotic arm to move the object 100 to the different carrier 200 in order to perform a cleaning step. In other words, when the disclosure uses the composite cleaning system to perform the different cleaning steps of the composite cleaning process, if the cleaning devices are optionally integrated together, use of the above-mentioned conveying system could be omitted, and it could help to reduce process costs, process time and increase production capacity.

Based on the above, the composite cleaning process and the composite cleaning system of the disclosure have the following advantages and features:

(1) By performing the laser reactive cleaning step and the gas or liquid reactive cleaning step to replace the conventional techniques of only cleaning objects with RCA cleaning agents and cleaning methods, the increasingly stringent process cleanliness requirements could be met.

(2) Using pulse energy with the gas or liquid reactive cleaning step could significantly reduce process steps, reduce water consumption, reduce chemical usage amounts and emissions, shorten process time and increase production capacity.

(3) Using pulse energy with the gas or liquid reactive cleaning step has good cleaning effects on various to-be-cleaned targets (such as organic matters, polymers, metal attachments, particles and native oxide layers), and a surface roughness is superior to traditional standard cleaning procedures.

(4) Using pulse energy with the gas or liquid reactive cleaning step, and also using a plasma device to provide a plasma, could further reduce a roughness of the to-be-cleaned area, remove small defects (crystal level), and achieve efficacies of high-temperature annealing and micro-growth epitaxy.

(5) The use of ozone (UV-Ozone) or ozone-deionized water (DI-Ozone) in the gas or liquid reactive cleaning step could combine or replace harmful chemicals in the traditional cleaning process, which could reduce water consumption, reduce chemical usage amounts and emissions, shorten process time and increase production capacity, and the cleaning effect and surface roughness are superior to traditional standard cleaning procedures.

(6) Using pulse energy to clean the to-be-cleaned area could cause the to-be-cleaned target located thereon to be ionized and move away after absorbing a high-energy light of a short pulse of a laser.

(7) By using pulse energy, the reactive cleaning ingredient of the gas or liquid reactive cleaning step could be ozone (gas or aqueous solution), and hydrofluoric acid (gas or aqueous solution), or RCA cleaning agent to meet cleanliness requirements of a process.

Note that the specification relating to the above embodiments should be construed as exemplary rather than as limitative of the present disclosure, with many variations and modifications being readily attainable by a person of average skill in the art without departing from the spirit or scope thereof as defined by the appended claims and their legal equivalents.

What is claimed is:

1. A composite cleaning process, at least comprising following steps of:
providing at least one object, the object having at least one to-be-cleaned target located on a to-be-cleaned area; and
using a composite cleaning system to perform a composite cleaning step on the to-be-cleaned area of the object, wherein the composite cleaning step comprises using a laser cleaning device to perform a laser reactive cleaning step on the to-be-cleaned area of the object and using a gas or liquid cleaning device to perform a gas or liquid reactive cleaning step on the to-be-cleaned area of the object, thereby either the laser reactive cleaning step or the gas or liquid reactive cleaning step is assisted by the other to improve a cleaning effect of the to-be-cleaned target on the to-be-cleaned area.

2. The composite cleaning process as claimed in claim 1, wherein the composite cleaning step performs the laser reactive cleaning step and the gas or liquid reactive cleaning step on the to-be-cleaned area of the object simultaneously, sequentially or in reverse order.

3. The composite cleaning process as claimed in claim 1, wherein the laser reactive cleaning step and the gas or liquid reactive cleaning step are respectively selected from a group consisting of dry cleaning method and wet cleaning method.

4. The composite cleaning process as claimed in claim 1, wherein the composite cleaning step performs the laser reactive cleaning step on a partial area or an entire area of the to-be-cleaned area of the object that has the to-be-cleaned target, and performs the gas or liquid reactive cleaning step on the partial area or the entire area of the to-be-cleaned area of the object.

5. The composite cleaning process as claimed in claim 1, wherein in the composite cleaning step, the laser cleaning device only performs the laser reactive cleaning step on the to-be-cleaned target on the to-be-cleaned area of the object.

6. The composite cleaning process as claimed in claim 1, wherein the gas or liquid reactive cleaning step performs a cleaning step selected from a group consisting of ozone cleaning method, hydrofluoric acid cleaning method and RCA cleaning agent method on the to-be-cleaned area of the object.

7. The composite cleaning process as claimed in claim 6, wherein the ozone cleaning method uses ozone-deionized water, ozone and/or hydrofluoric acid to clean the to-be-cleaned area of the object, the hydrofluoric acid cleaning method uses hydrofluoric acid to clean the to-be-cleaned area of the object, and the RCA cleaning agent method uses RCA cleaning agent to clean the to-be-cleaned area of the object.

8. The composite cleaning process as claimed in claim 1, wherein the gas or liquid cleaning device of the composite cleaning system further comprises an oscillating element for simultaneously oscillating the to-be-cleaned area of the object when performing the gas or liquid reactive cleaning step on the to-be-cleaned area of the object.

9. The composite cleaning process as claimed in claim 1, wherein the gas or liquid cleaning device of the composite cleaning system comprises a temperature control and adjustment element for performing control and adjustment of temperature when performing the gas or liquid reactive cleaning step on the to-be-cleaned area of the object.

10. The composite cleaning process as claimed in claim 1, wherein the composite cleaning system comprises a rotary worktable for performing the gas or liquid reactive cleaning step on the to-be-cleaned area of the object in a rotating state.

11. The composite cleaning process as claimed in claim 1, wherein the composite cleaning step of the composite cleaning system further comprises performing a grinding and polishing step on the to-be-cleaned area of the object before, between or after performing the laser reactive cleaning step and the gas or liquid reactive cleaning step.

12. The composite cleaning process as claimed in claim 11, wherein the composite cleaning step further comprises using a plasma device to provide a plasma to the to-be-cleaned area of the object before or after performing the grinding and polishing step.

13. The composite cleaning process as claimed in claim 11, wherein the composite cleaning step performs the grinding and polishing step on the to-be-cleaned area of the object in an environment containing ozone or ozone-deionized water.

14. The composite cleaning process as claimed in claim 1, wherein the composite cleaning step further comprises using a plasma device to provide a plasma to the to-be-cleaned area of the object.

15. The composite cleaning process as claimed in claim 12, wherein the plasma device is a remote plasma device, and the plasma is a remote plasma.

16. The composite cleaning process as claimed in claim 1, wherein the laser reactive cleaning step uses a laser beam to provide a pulse energy in a scanning manner to the to-be-cleaned area of the object.

17. The composite cleaning process as claimed in claim 16, wherein the laser reactive cleaning step causes the to-be-cleaned target on the to-be-cleaned area of the object to absorb the pulse energy and separate from the to-be-cleaned area of the object.

18. The composite cleaning process as claimed in claim 16, wherein the laser reactive cleaning step causes a liquid to absorb the pulse energy to generate an explosion pressure wave, thereby producing the cleaning effect on the to-be-cleaned target on the to-be-cleaned area of the object with assistance of the liquid.

19. The composite cleaning process as claimed in claim 16, wherein the laser reactive cleaning step provides the pulse energy to focus on a focal position adjacent to the to-be-cleaned target, thereby producing the cleaning effect on the to-be-cleaned target through a plasma shock wave formed at the focal position.

20. The composite cleaning process as claimed in claim 16, wherein the laser cleaning device provides the pulse energy in an adjustable manner to the to-be-cleaned area of the object through the laser beam in the laser reactive cleaning step.

21. The composite cleaning process as claimed in claim 1, wherein the to-be-cleaned target is selected from a group consisting of organic matters, polymers, metal impurities, particles, micro-rough structures and native oxide layers.

22. The composite cleaning process as claimed in claim 1, wherein the object is a crystal ingot, a wafer after cutting and before grinding and polishing, or a wafer after grinding and polishing.

23. The composite cleaning process as claimed in claim 1, wherein the object is a substrate, an object that has completed front-end-of-line (FEOL), an object that has completed back-end-of-line (BEOL) or a packaging object.

24. The composite cleaning process as claimed in claim 1, wherein the object is a semiconductor material selected from a group consisting of silicon, gallium arsenide, indium phosphide, gallium nitride and silicon carbide.

25. The composite cleaning process as claimed in claim 1, wherein the object is a low energy gap semiconductor (<1.5 eV) or a high energy gap semiconductor (>3.0 eV).

26. A composite cleaning system for performing a composite cleaning step on a to-be-cleaned area of at least one object, comprising:
a carrier for carrying the object, the object having at least one to-be-cleaned target located on the to-be-cleaned area of the object;
a laser cleaning device for performing a laser reactive cleaning step on the to-be-cleaned area of the object; and
a gas or liquid cleaning device for performing a gas or liquid reactive cleaning step on the to-be-cleaned area of the object, thereby either the laser reactive cleaning step or the gas or liquid reactive cleaning step is assisted by the other to improve a cleaning effect of the to-be-cleaned target on the to-be-cleaned area.

27. The composite cleaning system as claimed in claim 26, wherein the composite cleaning step performs the laser reactive cleaning step and the gas or liquid reactive cleaning step on the to-be-cleaned area of the object simultaneously, sequentially or in reverse order.

28. The composite cleaning system as claimed in claim 26, wherein the gas or liquid cleaning device performs a cleaning step selected from a group consisting of ozone cleaning method, hydrofluoric acid cleaning method and RCA cleaning agent method on the to-be-cleaned area of the object.

29. The composite cleaning system as claimed in claim 28, wherein the ozone cleaning method uses ozone-deionized water, ozone and/or hydrofluoric acid to clean the to-be-cleaned area of the object, the hydrofluoric acid cleaning method uses hydrofluoric acid to clean the to-be-cleaned area of the object, and the RCA cleaning agent method uses RCA cleaning agent to clean the to-be-cleaned area of the object.

30. The composite cleaning system as claimed in claim 26, wherein the gas or liquid cleaning device further comprises a tank, wherein the to-be-cleaned area of the object is performed with the gas or liquid reactive cleaning step in the tank.

31. The composite cleaning system as claimed in claim 28, wherein the gas or liquid cleaning device further comprises a tank, wherein a number of the object is plural, and the objects are placed in the tank at the same time to perform the gas or liquid reactive cleaning step.

32. The composite cleaning system as claimed in claim 26, wherein the gas or liquid cleaning device of the composite cleaning system further comprises an oscillating element for simultaneously oscillating the to-be-cleaned area of the object when performing the composite cleaning step on the to-be-cleaned area of the object.

33. The composite cleaning system as claimed in claim 26, wherein the gas or liquid cleaning device of the composite cleaning system comprises a temperature control and adjustment element for controlling and adjusting a temperature of the composite cleaning step when performing the composite cleaning step on the to-be-cleaned area of the object.

34. The composite cleaning system as claimed in claim 26, wherein the carrier is a rotary worktable for rotating the object, thereby enabling the gas or liquid cleaning device to perform the gas or liquid reactive cleaning step on the to-be-cleaned area of the object in a rotating state.

35. The composite cleaning system as claimed in claim 26, wherein the gas or liquid cleaning device comprises a gas or liquid supply source, and the gas or liquid supply source is selected from a group consisting of an ozone-deionized water generating device, an ozone generating device, a hydrofluoric acid supply device and an RCA cleaning agent supply device.

36. The composite cleaning system as claimed in claim 26, further comprising performing a grinding and polishing step on the to-be-cleaned area of the object before, between or after performing the laser reactive cleaning step and the gas or liquid reactive cleaning step.

37. The composite cleaning system as claimed in claim 36, further comprising a plasma device, wherein the plasma device provides a plasma to the to-be-cleaned area of the object before or after performing the grinding and polishing step.

38. The composite cleaning system as claimed in claim 36, wherein the composite cleaning step performs the grinding and polishing step on the to-be-cleaned area of the object in an environment containing ozone or ozone-deionized water.

39. The composite cleaning system as claimed in claim 26, wherein the composite cleaning step further comprises using a plasma device to provide a plasma to the to-be-cleaned area of the object.

40. The composite cleaning system as claimed in claim 37, wherein the plasma device is a remote plasma device, and the plasma is a remote plasma.

41. The composite cleaning system as claimed in claim 26, wherein the laser cleaning device generates a laser beam to provide a pulse energy in a scanning manner to the to-be-cleaned area of the object.

42. The composite cleaning system as claimed in claim 41, wherein the laser cleaning device causes the to-be-cleaned target on the to-be-cleaned area of the object to absorb the pulse energy and separate from the to-be-cleaned area of the object in the laser reactive cleaning step.

43. The composite cleaning system as claimed in claim 41, wherein the laser cleaning device causes a liquid to absorb the pulse energy to generate an explosion pressure wave in the laser reactive cleaning step, thereby producing the cleaning effect on the to-be-cleaned target on the to-be-cleaned area of the object with assistance of the liquid.

44. The composite cleaning system as claimed in claim 41, wherein the laser cleaning device provides the pulse energy to focus at a focal position that is a distance away from the to-be-cleaned target in the laser reactive cleaning step, thereby producing the cleaning effect on the to-be-cleaned target on the to-be-cleaned area through a plasma shock wave formed at the focal position.

45. The composite cleaning system as claimed in claim 41, wherein the laser cleaning device provides the pulse energy in an adjustable manner to the to-be-cleaned area of the object through the laser beam in the laser reactive cleaning step.

46. The composite cleaning system as claimed in claim 41, wherein the laser beam is a pulsed nanosecond laser with a wavelength of 1,064 nm.
